(19) United States
(12) Patent Application Publication
(10) Pub. No.: US 2017/0196077 A1
(43) Pub. Date: Jul. 6, 2017

(54) RIGID FLEXIBLE BOARD AND METHOD FOR MANUFACTURING THE SAME

(71) Applicant: FUJITSU LIMITED, Kawasaki-shi (JP)

(72) Inventors: Shigeo IRIGUCHI, Kawasaki (JP); Naoki Nakamura, Hachioji (JP); Mitsunori Abe, Kawasaki (JP); Nobuo Taketomi, Kodaira (JP); Kiyoyuki Hatanaka, Kawasaki (JP); Ryo Kanai, Kawasaki (JP)

(73) Assignee: FUJITSU LIMITED, Kawasaki-shi (JP)

(21) Appl. No.: 15/375,718

(22) Filed: Dec. 12, 2016

(30) Foreign Application Priority Data
Jan. 6, 2016 (JP) 2016-001175

(51) Int. Cl. H05K 1/02; H05K 3/12; H05K 1/18

(52) U.S. Cl. CPC H05K 1/028; H05K 1/185; H05K 3/1258; H05K 2201/09018

(57) ABSTRACT

A rigid flexible board includes: a substrate that has flexibility and electric insulation; a protective layer formed at a central portion of each of opposite surfaces of the substrate; and a plurality of core layers partially covering the protective layer and formed at a circumferential edge of each of the opposite surfaces of the substrate; wherein a gap is formed close to a center of the substrate in a thickness direction thereof between the core layers and the protective layer.

### CROSS-REFERENCE TO RELATED APPLICATION

This application is based upon and claims the benefit of priority of the prior Japanese Patent Application No. 2016-001175, filed on Jan. 6, 2016, the entire contents of which are incorporated herein by reference.

### FIELD

The embodiments discussed herein are related to a rigid flexible board and a method for manufacturing the same.

### BACKGROUND

In a manufacturing method of a flex-rigid multilayer wiring board in which a plurality of rigid wiring portions are connected to each other while a flexible wiring portion is interposed therebetween, there is a technique of making a width of an opening of the rigid wiring board, which becomes a convex side when the flexible wiring portion is bent, smaller than a width of an opening of an interlayer adhesive sheet.

In a board (a rigid flexible board) having a structure in which a plurality of core layers are connected to each other through a flexible substrate (a flexible layer), it is required to suppress the occurrence of a crack when the substrate is curved. Especially, in the rigid flexible board, it is required to suppress the occurrence of a crack even when the substrate is curved in any direction.

The following is a reference document.
[Document 1] Japanese Laid-Open Patent Publication No. 8-288654.

### SUMMARY

According to an aspect of the embodiment, a rigid flexible board includes: a substrate that has flexibility and electric insulation; a protective layer formed at a central portion of each of opposite surfaces of the substrate; and a plurality of core layers partially covering the protective layer and formed at a circumferential edge of each of the opposite surfaces of the substrate; wherein a gap is formed close to a center of the substrate in a thickness direction thereof between the core layers and the protective layer.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view illustrating a rigid flexible board of a first embodiment;

FIG. 2 is a cross-sectional view illustrating an electronic device having the rigid flexible board of the first embodiment;

FIG. 3 is a cross-sectional view illustrating an enlarged portion of the rigid flexible board of the first embodiment;

FIG. 4A is a cross-sectional view illustrating a state of the rigid flexible board of the first embodiment during the manufacture thereof;

FIG. 4B is a cross-sectional view illustrating a state of the rigid flexible board of the first embodiment during the manufacture thereof;

FIG. 4C is a cross-sectional view illustrating a state of the rigid flexible board of the first embodiment during the manufacture thereof;

FIG. 4D is a cross-sectional view illustrating a state of the rigid flexible board of the first embodiment during the manufacture thereof;

FIG. 4E is a cross-sectional view illustrating a state of the rigid flexible board of the first embodiment during the manufacture thereof;

FIG. 4F is a cross-sectional view illustrating a state of the rigid flexible board of the first embodiment during the manufacture thereof;

FIG. 4G is a cross-sectional view illustrating a state of the rigid flexible board of the first embodiment during the manufacture thereof;

FIG. 4H is a perspective view illustrating a state of the rigid flexible board of the first embodiment during the manufacture thereof;

FIG. 5 is a cross-sectional view illustrating an enlarged portion of a rigid flexible board of a first comparative example;

FIG. 6 is a cross-sectional view illustrating an enlarged portion of a rigid flexible board of a second embodiment;

FIG. 7 is a cross-sectional view illustrating a state of curving the rigid flexible board;

FIG. 8 is a cross-sectional view illustrating an enlarged portion of a rigid flexible board of a modification of the second embodiment; and

FIG. 9 is a cross-sectional view illustrating a rigid flexible board of a third embodiment.

### DESCRIPTION OF EMBODIMENTS

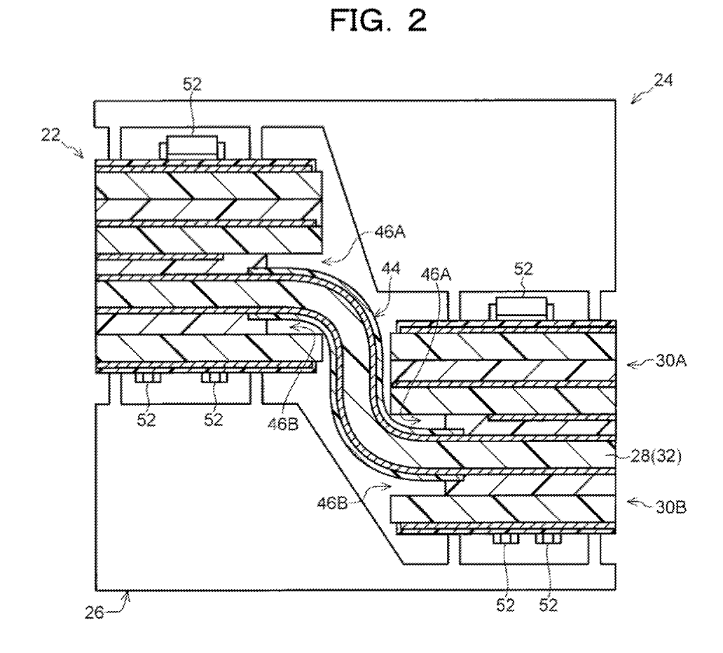

A rigid flexible board of a first embodiment will be described in detail based on the accompanying drawings. A rigid flexible board 22 is placed inside, for example, a case 26 of an electronic device 24, as illustrated in FIG. 2. Examples of the electronic device 24 may include electric home appliances or information processors (e.g., a digital camera, a laptop-type (note-type) computer, and a mobile phone). In addition, the electronic device 24 may be applied to, for example, a control device that is equipped in an automobile to control the engine and others.

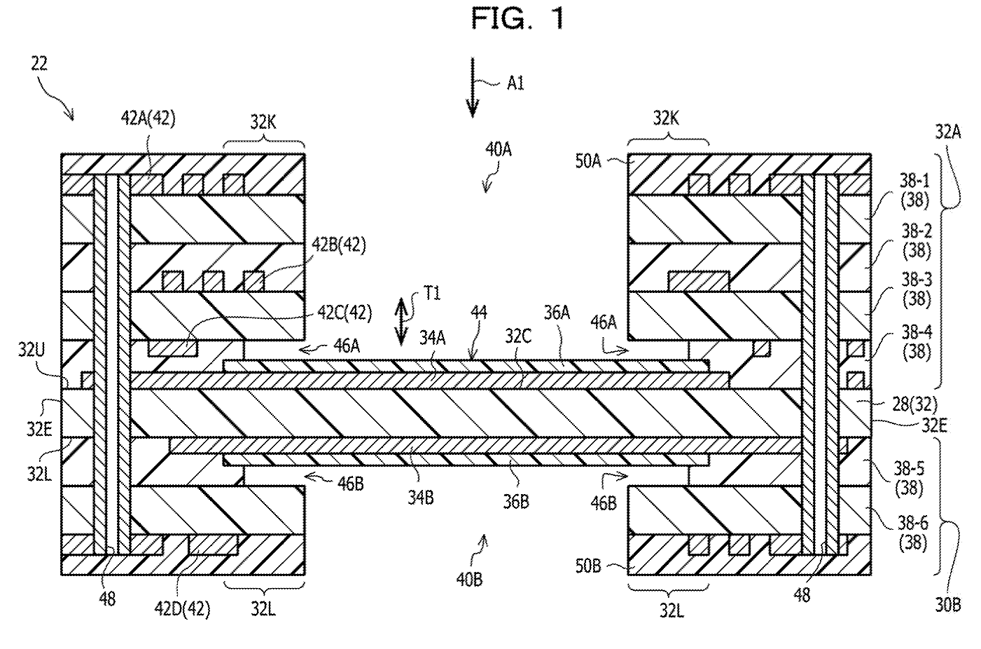

Hereinafter, for the convenience of descriptions, the upper side in each of FIGS. 1 and 2 will be regarded as the upper side in the rigid flexible board 22, and the lower side in each of FIGS. 1 and 2 will be regarded as the lower side in the rigid flexible board 22. However, the upper and lower sides are irrelevant to the upper and lower sides in the circumstance where the rigid flexible board 22 is actually used, and the direction (the up-and-down direction relationship) of the rigid flexible board 22 when the rigid flexible board 22 is used is not specifically limited.

As illustrated in FIGS. 1 and 2, the rigid flexible board 22 of the first embodiment includes a plate-shaped flexible layer 32 having flexibility and an insulating property. The flexible layer 32 may also serve as a substrate 28 in the rigid flexible board 22.

In the present embodiment, glass epoxy is used as an example of a material for the flexible layer 32.

The “flexibility” of the flexible layer 32 indicates flexibility (easily deformable) sufficient to cause the flexible layer 32 to be curved in the thickness direction thereof such that the rigid flexible board 22 may be placed in a predetermined position inside the case 26 of the electronic device 24, as illustrated in FIG. 2.

First pattern layers 34A and 34B made of a conductive material (e.g., copper) are formed at central portions 32C (the central portions in the width direction in FIG. 1) on the opposite surfaces (the upper surface 32U and the lower surface 32L) of the flexible layer 32 when the flexible layer 32 is viewed from the cross section thereof. The first pattern layers 34A and 34B serve as portions of a predetermined circuit pattern formed on the rigid flexible board 22. The first pattern layers 34A and 34B may have different pattern shapes.

Solder resist layers 36A and 36B are laminated on the opposite surfaces of the flexible layer 32 to cover predetermined ranges of the first pattern layers 34A and 34B, respectively. The solder resist layers 36A and 36B are film-shaped members that are formed of a material having the insulating property (e.g., an epoxy resin) and protect the first pattern layers 34A and 34B. For example, the solder resist layers 36A and 36B suppress an unexpected conduction due to the attachment of solders or foreign objects to the portions of the first pattern layers 34A and 34B that are not required to be conducted. Each of the solder resist layers 36A and 36B is an example of a protective layer.

As the solder resist layers 36A and 36B, for example, film-shaped polyamide may also be used, in addition to the above-mentioned epoxy resin.

Core layers 30A and 30B are formed on the opposite surfaces of the flexible layer 32 at the circumferential edge 32E side thereof. In the present embodiment, each core layer 30A includes a plurality of insulating layers 38 (four (4) layers) formed of a material having the insulating property (a first insulating layer 38-1, a second insulating layer 38-2, a third insulating layer 38-3, and a fourth insulating layer 38-4 in this order from the upper side).

Each core layer 30B also includes a plurality of insulating layers 38 (two (2) layers) formed of a material having the insulating property (a fifth insulating layer 38-5 and a sixth insulating layer 38-6 in this order from the upper side).

As for the insulating layers 38, the same material as that of the flexible layer 32 may be used. In the present embodiment, glass epoxy is used for the flexible layer 32, and also glass epoxy is used for the insulating layers 38.

As understood from FIG. 1, the core layers 30A are disposed at the opposite sides of the rigid flexible board 22 in the width direction thereof. The rigid flexible board 22 has a structure where an opening 40A is formed between the opposite core layers 30A.

The core layers 30B are also disposed at the opposite sides of the rigid flexible board 22 in the width direction thereof, and the rigid flexible board 22 has a structure where an opening 40B is formed between the opposite core layers 30B.

The openings 40A and 40B are formed at the same position when viewed from the upper side (in the direction of the arrow A1). In other words, the portions where the openings 40A and 40B are formed are a partially thinned curve portion 44 of the rigid flexible board 22. In the curve portion 44, the substrate 28 (the flexible layer 32) may be curved. Further, an opening size AA of the opening 40A and an opening size BA of the opening 40B may be different from each other.

Second pattern layers 42 are formed at predetermined positions between interlayers of the insulating layers 38 and at predetermined positions on the upper surface of the first insulating layer 38-1 and the lower surface of the sixth insulating layer 38-6. In the present embodiment, a second pattern layer 42A is formed on the upper surface of the first insulating layer 38-1, second pattern layers 42B and 42C are formed on the opposite surfaces of the third insulating layer 38-3, and a second pattern layer 42D is formed on the lower surface of the sixth insulating layer 38-6. Since the first pattern layers 34A and 34B are formed on the flexible layer 32, the total number of the pattern layers on the entire rigid flexible board 22 is 6. That is, among the 6 pattern layers, the fourth and fifth layers from the upper side are formed on the flexible layer 32.

A portion 32K of the core layer 30A which is close to the central portion 32C covers the solder resist layer 36A when viewed from the upper side (in the direction of the arrow A1). Identically, a portion 32L of the core layer 30B which is close to the central portion 32C also covers the solder resist layer 36B. Here, the term “cover” indicates overlapping when viewed in the direction of the arrow A1 or in the opposite direction thereof in FIG. 1 and may include no contact.

The core layer 30A has a gap 46A between the core layer 30A and the solder resist layer 36A in the thickness direction (the direction of the arrow T1) of the substrate 28 (the solder resist layer 36A). The gap 46A is formed close to the central portion 32C with respect to the core layer 30A and the portion 32K covering the solder resist layer 36A. Identically, the core layer 30B has a gap 46B between the core layer 30B and the solder resist layer 36B in the thickness direction (the direction of the arrow T1) of the substrate 28 (the solder resist layer 36A). The gap 46B is formed close to the central portion 2C with respect to the core layer 30B and the portion 32L covering the solder resist layer 36B.

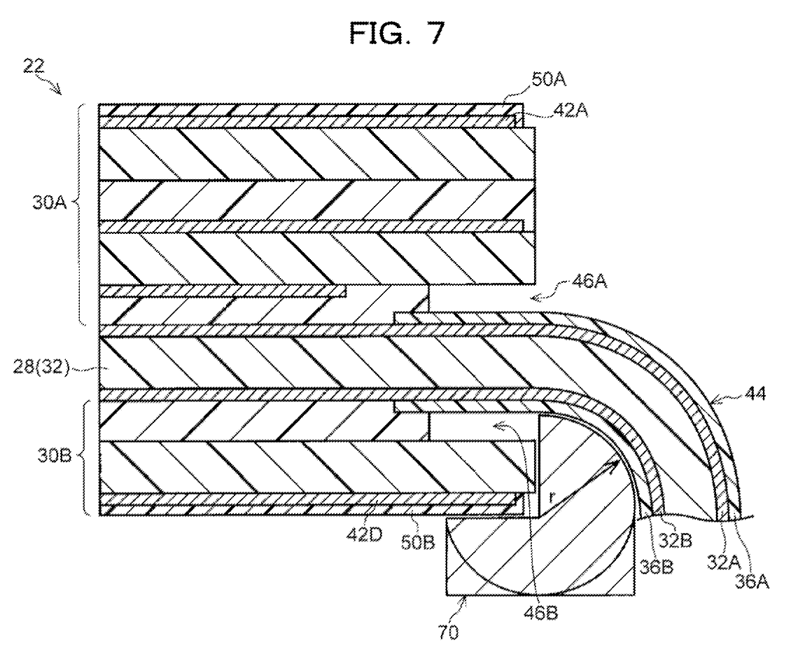

As illustrated in FIG. 2, the rigid flexible board 22 may be equipped inside the case 26 of the electronic device 24 in a state of being curved at the curve portion 44. Further, as described later, the rigid flexible board 22 may be formed in a shape in which the curve portion 44 is curved by using a jig 70 (see FIG. 7).

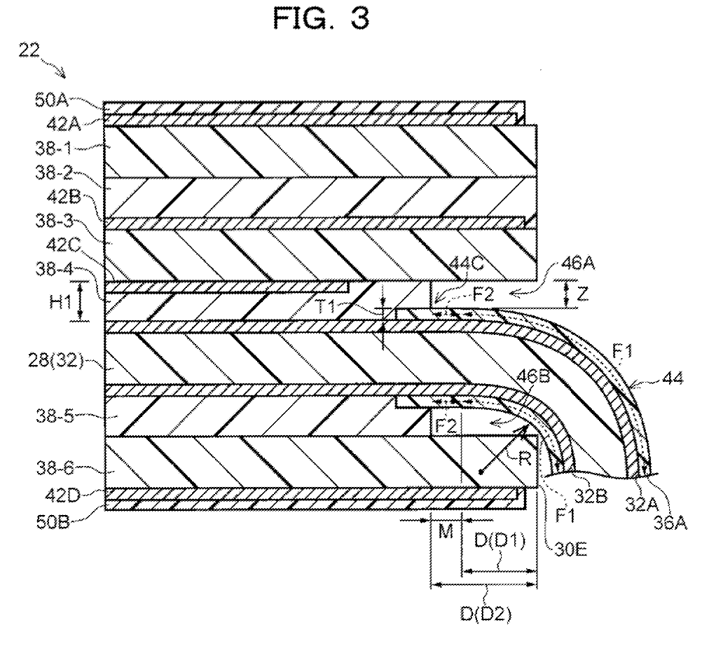

As illustrated in FIG. 3, the curvature radius R of the curved portion in the state where the curve portion 44 is curved is R. The height of each of the gaps 46A and 46B in the thickness direction thereof (the direction of the arrow T1) is z. The depth D(=D1) of the gap 46A toward the circumferential edge 32E side from the central portion 32C side (the internal edge 30E of the core layer) is formed to be equal to or more than

D1=\sqrt{R²−(R−z)²} (1)

which is obtained by using the curvature radius R and the height z. The gaps 46A and 46B may be different from each other in the depth D or the height z.

As illustrated in FIG. 2, the rigid flexible board 22 may be placed inside the case 26 of the electronic device 24 in the state where the curve portion 44 is curved. Especially, in the example illustrated in FIG. 2, the right portion and the left portion of the rigid flexible board 22 are positioned at different heights, and the curve portion 44 has an upwardly convexly curved portion and a downwardly convexly curved portion. When the curve portion 44 is curved in this way, the right portion and the left portion of the rigid flexible board 22 may be positioned at different heights. For example, even when the space where the rigid flexible board 22 is to be placed is narrow, the rigid flexible board 22 may be placed inside the case 26 by positioning the right portion and the left portion of the rigid flexible board 22 at different heights.

In addition, even when the heights of the right portion and the left portion of the rigid flexible board 22 are the same, the curve portion 44 may be caused to be curved in order to circumvent various components, wiring or the like within the case 26.

At the position where each of the core layers 30A and 30B is formed, a through hole 48 is formed to penetrate through the rigid flexible board 22 in the thickness direction thereof. The through hole 48 conducts the first pattern layers 34A and 34B or the second pattern layers 42A, 42B, 42C, and 42D at predetermined positions.

Solder resist layers 50A and 50B are also formed on the upper surface of the core layer 30A and the lower surface of the core layer 30B, respectively. The solder resist layers 50A and 50B cover and protect the second pattern layers 42A and 42D, respectively.

As illustrated in FIG. 2, various electronic parts 52 are equipped at predetermined positions on the upper surface and the lower surface of the rigid flexible board 22.

Next, a manufacturing method of the rigid flexible board 22 of the present embodiment will be described.

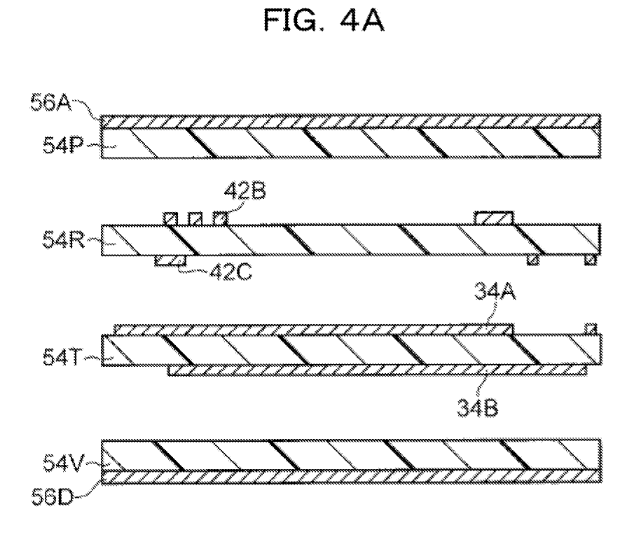

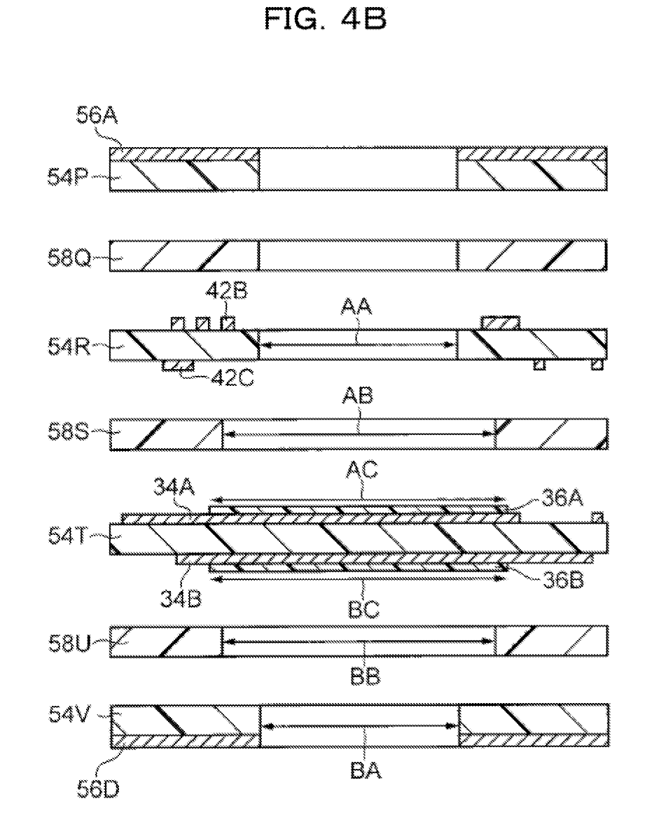

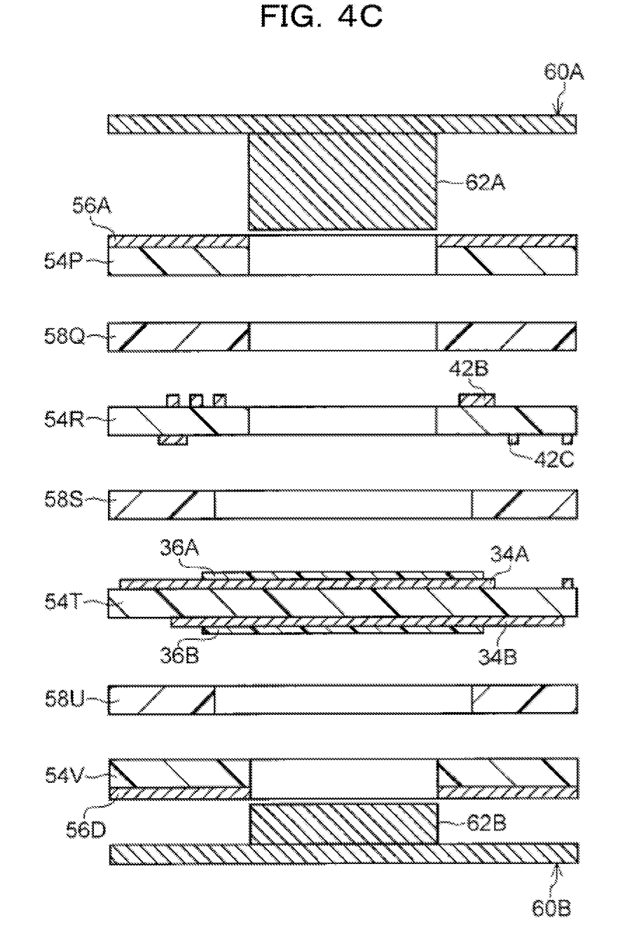

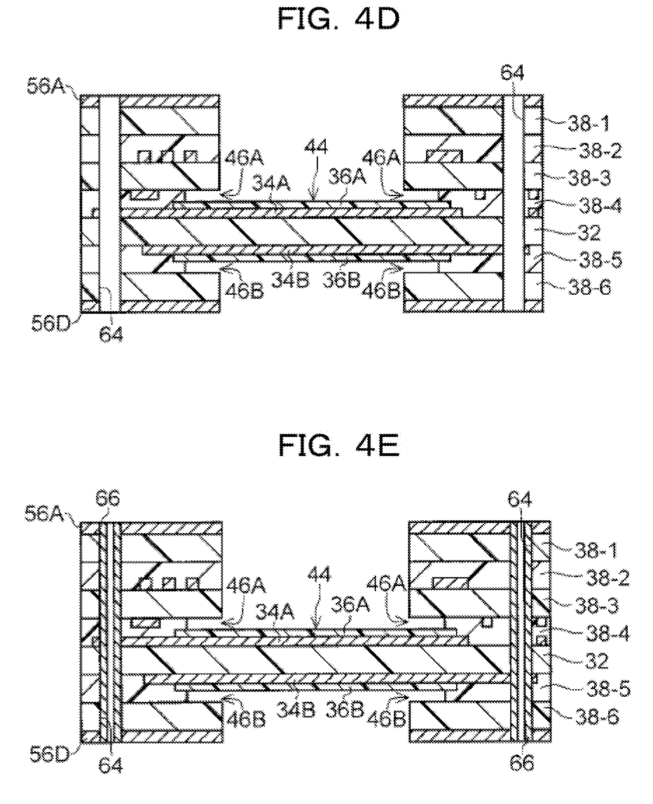

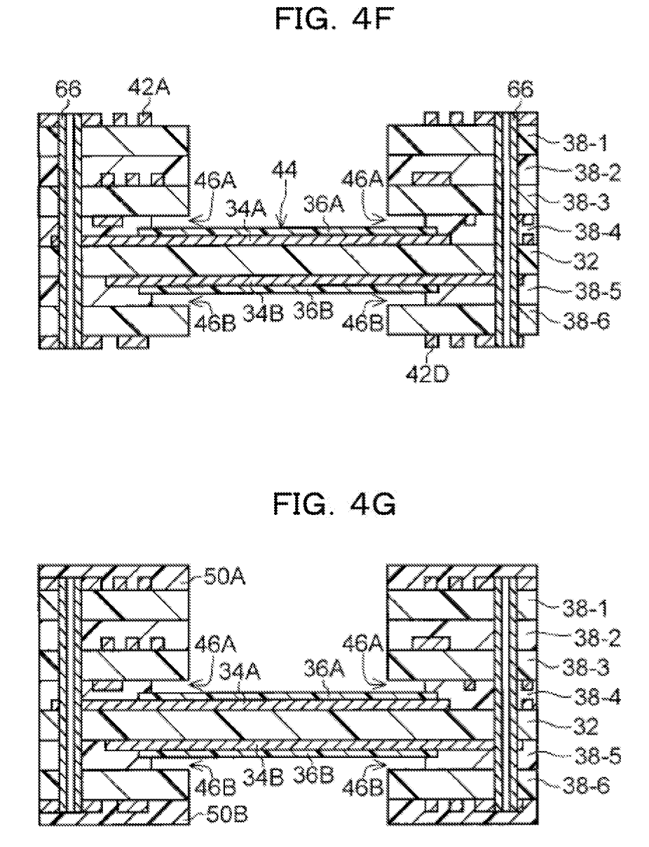

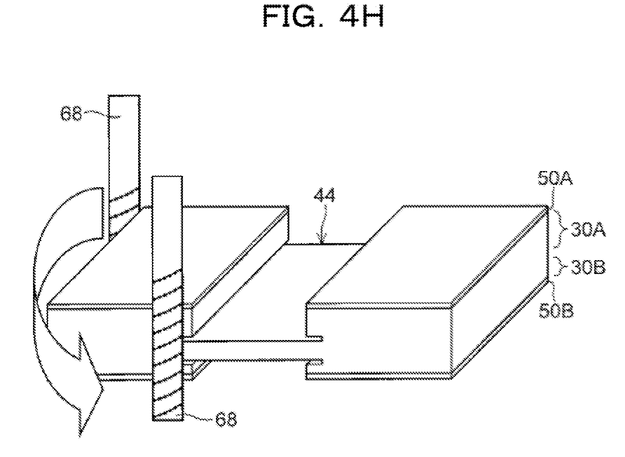

As illustrated in FIG. 4A, a plurality of (four (4) in the present embodiment) plate-shape core materials 54P, 54R, 54T, and 54V are first prepared. The core materials 54P, 54R, 54T, and 54V are formed of, for example, glass epoxy. As described later, the core material 54P corresponds to the first insulating layer 38-1, the core material 54R corresponds to the third insulating layer 38-3, the core material 54P corresponds to the flexible layer 32, and the core material 54V corresponds to the sixth insulating layer 38-6.

A copper foil 56A (a so-called solid pattern) is formed on the upper surface of the core material 54P to cover the entire upper surface. Identically, a copper foil 56D (a solid pattern) is also formed on the lower surface of the core material 54V to cover the entire lower surface. On the upper surface and the lower surface of the core material 54R, circuit patterns each having a predetermined shape are formed to serve as portions of the second pattern layers 42B and 42C. Further, on the upper surface and the lower surface of the core material 54T, circuit patterns each having a predetermined shape are formed to serve as the first pattern layers 34A and 34B.

Then, as illustrated in FIG. 4B, prepregs 58Q, 58S, and 58U are disposed among the core materials 54P, 54R, 54T, and 54V.

The portions of the core materials 54P and 54R and the prepreg 58Q which correspond to the opening 40A are punched into a predetermined opening size AA by a punching processing or the like. Identically, the portion of the core material 54V which corresponds to the opening 40B is punched into a predetermined opening size BA by a punching processing or the like.

Meanwhile, the portion of the prepreg 58S which corresponds to the opening 40A and the gap 46A is punched into a predetermined opening size AB by a punching processing or the like. The opening size AA and the opening size AB are in the relationship of the opening size AA<the opening size AB.

The portion of the prepreg 58U which corresponds to the opening 40B and the gap 46B is punched into a predetermined opening size BB by a punching processing or the like. The opening size BA and the opening size BB are in the relationship of the opening size BA<the opening size BB.

The prepregs 58Q, 58S, and 58U are formed of, for example, glass epoxy. As described later, the prepregs 58Q, 58S, and 58U exhibit their adhesive performance and are cured when they are adhered to and integrated with the core materials 54P, 54R, 54T, and 54V by a press. By the curing, the prepregs 58Q, 58S, and 58U become the second insulating layer 38-2, the fourth insulating layer 38-4, and the fifth insulating layer 38-5, respectively.

Among the prepregs 58Q, 58S, and 58U of the present embodiment, the prepregs 58S and 58U to be in contact with the flexible layer 32 are made of a so-called low flow material having low resin fluidity.

The solder resist layers 36A and 36B are formed on the first pattern layers 34A and 34B of the core material 54T. The widths AC and BC of the solder resist layers 36A and 36B are larger than the opening sizes AB and BB of the punched portions of the prepregs 58S and 58U, respectively. In addition, the widths AC and BC of the solder resist layers 36A and 36B are widths sufficient not to cover the entire first pattern layers 34A and 34B and not to cover some portions of the first pattern layers 34A and 34B. For example, in the example illustrated in FIG. 4B, the opposite side portions of the first pattern layers 34A and 34B in the width direction thereof protrude from the solder resist layers 36A and 36B. Accordingly, a strong adhesive force between the first pattern layers 34A and 34B and the prepregs 58S and 58U may be secured, as compared to the structure in which the solder resist layers 34A and 36B cover the entire first pattern layers 34A and 34B.

Then, as illustrated in FIG. 4C, the core materials 54P, 54R, 54T, and 54V and the prepregs 58Q, 58S, and 58U in the state of being alternately arranged are integrated with each other into a laminated state by using press jigs 60A and 60B within a press device.

Especially, the integrating work is facilitated by collectively laminating and pressing the core materials 54P, 54R, 54T, and 54V and the prepregs 58Q, 58S, and 58U.

As illustrated in FIG. 4B, the widths AC and BC of the solder resist layers 34A and 36B are larger than the opening sizes AB and BB. Hence, in the laminated state, the ends of the solder resist layers 36A and 36B in the width direction thereof overlap with the prepregs 58S and 58U. In other words, portions of the prepregs 58S and 58U cover the opposite side portions of the solder resist layers 36A and 36B. Accordingly, the adhesive force at the boundaries between the solder resist layers 36A and 36B and the prepregs 58S and 58U is weak, as compared to the structure where no overlapping portions exist.

In addition, the opposite side portions of the first pattern layers 34A and 34B in the width direction thereof protrude from the solder resist layers 36A and 36B, and the prepregs 58S and 58U overlap with the protruding portions.

The solder resist layers 36A and 36B may be first thermally cured prior to laminating and pressing the core materials 54P, 54R, 54T, and 54V and the prepregs 58Q, 58S, and 58U. When the pressing is performed after curing the solder resist layers 36A and 36B, the melting of the solder resist layers 36A and 36B may be suppressed at the pressing time.

In addition, since the surfaces of the solder resist layers 36A and 36B become smooth (are not roughened) as a result of the thermal curing, the adhesive force to the prepregs 58S and 58U becomes weak.

In actuality, a deviation of the formation position of the solder resist layer 36A, a deviation of the lamination position of the core material 54T and the prepreg 58S or the like may occur. In consideration of the deviations, the overlapping length between the solder resist layers 36A and 36B and the prepregs 58S and 58U is set to a predetermined length or more (e.g., 0.25 mm or more).

The pressure inside the press device is reduced (in a so-called vacuum state) during the pressing, in order to avoid, for example, a formation of an unexpected cavity between layers. In order to suppress the portion corresponding to the curve portion 44 (see FIG. 1) from being inadvertently deformed in the pressure reduced state, the press jigs 60A and 60B are provided with convex portions 62A and 62B corresponding to the openings 40A and 40B. Accordingly, the rigid flexible board 22 (the substrate 28) having a desired structure may be manufactured while maintaining the shape of the portion which is to serve as the curve portion 44 (without inadvertent deformation). As the prepregs 58Q, 58S, and 58U are cured, the second insulating layer 38-2, the fourth insulating layer 38-4, and the fifth insulating layer 38-5 are formed on the substrate 28.

The prepregs 58S and 58U in contact with the flexible layer 32 are made of a so-called low flow material having low resin fluidity. Hence, the inadvertent deformation of the prepregs 58S and 58U may be suppressed, and the shape of the gaps 46A and 46B may be maintained.

Thereafter, as illustrated in FIG. 4D, through holes 64 are formed at predetermined positions on the portions of the flexible layer 32 where the core layers 30A and 30B are laminated, and then, a plating 66 is performed on the through holes 64.

In addition, as illustrated in FIG. 4F, the copper in the unnecessary portions of the copper foils 56A and 56D is removed thereby forming predetermined circuit patterns (the second pattern layers 42A and 42D).

Thereafter, as illustrated in FIG. 4G, the solder resist layers 50A and 50B are formed on the upper surface of the core material 54P and the lower surface of the core material 54V.

Then, as illustrated in FIG. 4H, the external shape of the substrate 28 is processed by using the jig 68 or the like so that the rigid flexible board 22 is obtained.

In the above-described manufacturing method of the rigid flexible board 22, the shape of the substrate or the prepregs or the number of laminated layers may be determined to correspond to the position where the curve portion 44 is to be formed, prior to pressing the core materials 54P, 54R, 54T, and 54V and the prepregs 58Q, 58S, and 58U. In other words, when the shape of the core materials 54P, 54R, 54T, and 54V and the prepregs 58Q, 58S, and 58U, the number of laminated layers and others are determined in advance, the curve portion 44 may be provided at an arbitrary position.

In the rigid flexible board 22, among the seven (7) insulating layers, an arbitrary insulating layer other than the insulating layers 38 at the opposite ends of the rigid flexible board 22 in the thickness direction thereof is formed as the flexible layer 32 so that the structure having the gaps 46A and 46B may be implemented. Since the arbitrary insulating layer may be formed as the flexible layer 32, the degree of freedom in the design of the rigid flexible board 22 or the degree of freedom in the equipment in the electronic device 24 is high.

Next, the operation of the rigid flexible board 22 of the present embodiment will be described.

As illustrated in FIG. 2, the rigid flexible board 22 may be used in the state where the curve portion 44 of the substrate 28 is curved. Since the rigid flexible board 22 has the gap 46A between the solder resist layer 36A and the core layer 30A, the crack of the solder resist layer 36A (or the flexible layer 32) may be suppressed when the curve portion 44 is curved as described above. This point will be described in detail hereinafter.

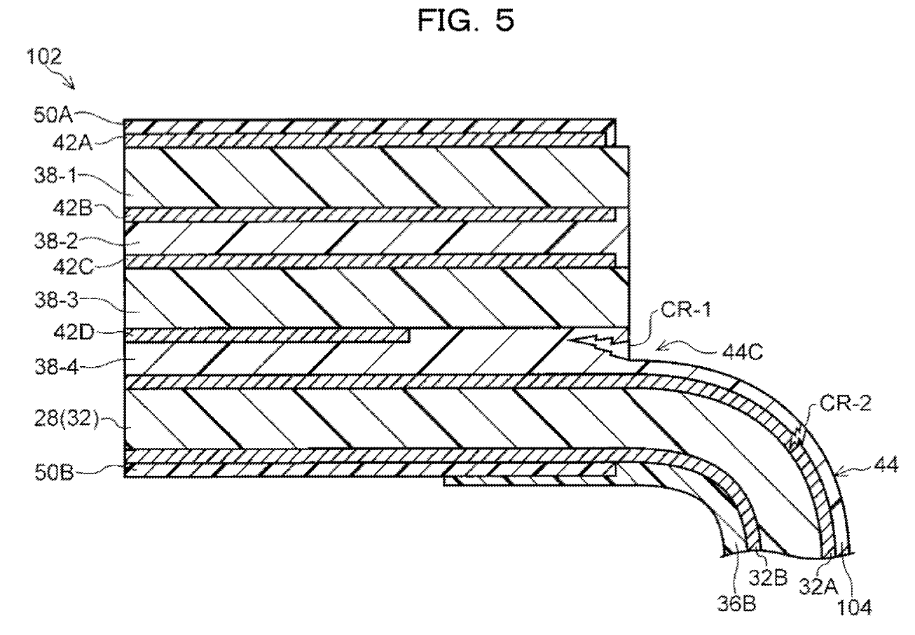

FIG. 5 represents a rigid flexible board 102 having a structure in which the gaps of the first embodiment do not exist, as a first comparative example. The rigid flexible board 102 of the first comparative example does not include the fifth insulating layer 38-5 and the sixth insulating layer 38-6 included in the rigid flexible board 22 of the first embodiment. In addition, the gaps 46A and 46B are not provided. In the curve portion 44, the upper solder resist layer 36A (see FIG. 3) is not provided, and a coating 104 is formed by extending from the fourth insulating layer 38-4 to coat the curve portion 44.

In the rigid flexible board 102 of the first comparative example, a large stress force may act on a root portion 44C of the curve portion 44 which is the boundary between the curve portion 44 and the core layer 30A in the state where the curve portion 44 is curved, thereby causing a crack CR-1. Further, for example, when the curvature radius of the curved shape is small, a crack CR-2 may also occur at the portion of the curve portion 44 which is coated with the coating 104. Although the covering portion 104 is formed by the fourth insulating layer 38-4, the crack CR-2 may easily occur when irregularities such as glass fiber have been formed on the surface of the fourth insulating layer 38-4.

Meanwhile, the rigid flexible board 22 of the first embodiment has the gaps 46A and 46B each having the depth D which is equal to or more than D1 obtained from the equation (1) above, and the root portion 44C of the curve portion 44 is positioned inside the gap 46A. Hence, as illustrated in FIG. 3, the portion where the substrate 28 is curved with a large curvature does not exist in the root portion 44C, in the state where the substrate 28 is curved at the curve portion 44. In other words, the portion of the substrate 28 (the flexible layer 32) which is curved with a large curvature does not reach the root portion 44C. Since a stress F2 at the root portion 44C in the direction of the tension acting on the solder resist layer 36A outside the curve becomes small in comparison with a stress F1 at portions other than the root portion 44C, the occurrence of a crack of the solder resist layer 36 may be suppressed. Further, in the solder resist layer 36B outside the curve as well, the stress in the pressing direction becomes small, and hence, wrinkles of the solder resist layer 36B or the detachment thereof from the substrate 28 may be suppressed.

In the rigid flexible board 22 of the present embodiment, the gaps 46A and 46B are formed on the opposite surfaces (the upper surface and the lower surface) of the substrate 28. Accordingly, even when the curve portion 44 is curved in the direction opposite to the direction illustrated in FIG. 3, wrinkles or the detachment of the solder resist layers 36A and 36B may be suppressed. Actually, in the example of the electronic device 24 illustrated in FIG. 2, the curve portion 44 includes the portions curved in different directions.

Further, in the present embodiment, the solder resist layers 36A and 36B are in the state where the surfaces thereof are smooth due to the thermal curing, and the adhesive force between the solder resist layers 36A and 36B and the prepregs 58S and 58U are weak. Hence, when a stress acts on the root portion 44C, the contacted portions between the solder resist layers 36A and 36B and the prepregs 58S and 58U may be opened due to the stress, thereby alleviating the stress.

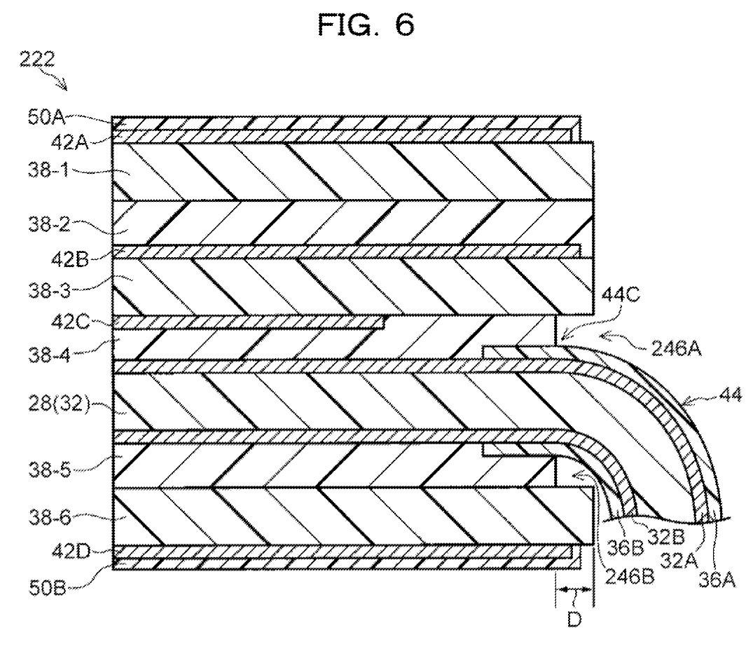

FIG. 6 represents a rigid flexible board 222 of a second embodiment. In the second embodiment, the same components, members and others as those of the first embodiment will be denoted by the same reference numerals as used in the first embodiment, and detailed descriptions thereof will be omitted. Further, since an electronic device of the second embodiment may adopt the same structure as that of the electronic device 24 of the first embodiment, illustration and detailed descriptions thereof will be omitted.

In the rigid flexible board 222 of the second embodiment, while gaps 246A and 246B are provided, the depth D of each of the gaps 246A and 246B is shorter than the depth D of each of the gaps 46A and 46B of the first embodiment.

Even in the structure in which the depths D of the gaps 246A and 246B are short, the portion of the curve portion 44 which has a large curvature when the curve portion 44 is curved does not reach the root portion 44C, so that the occurrence of a crack of the solder resist layer 36A at the root portion 44 may be suppressed. Further, wrinkles or the detachment of the solder resist layer 36B outside the curve may also be suppressed.

The sizes, especially, the depths D of the gaps 46A and 46B of the first embodiment or the gaps 246A and 246B of the second embodiment may be deep to the extent that the portion curved with a large curvature to reach the root portion 44C in the state where the curve portion 44 is curved.

Here, the height z of each of the gaps 46A, 46B, 246A, and 246B and the curvature radius R of the curve portion 44 are used. In this case, when the depth D is equal to or more than D1, the structure in which the portion curved with a large curvature is suppressed from reaching the root portion 44C is obtained. That is, when the height z of each of the gaps 46A, 46B, 246A, and 246B and the curvature radius R of the curve portion 44 may be determined, as long as the depth D is equal to or more than D1 of the equation (1) above, the occurrence of a crack may be suppressed.

For example, in the first embodiment, assuming a case where the height H1 of the fourth insulating layer 38-4 is 0.1 mm, and the thickness T1 of the solder resist layer 36B is 0.03 mm, the height z of each of the gaps 46A and 46B is 0.07 mm.

Assuming that the curvature radius R of the curve portion 44 is 4 mm, when the curvature radius is substituted into the equation (1) above, D1=0.73 mm.

A further margin may be added to the value of D1 obtained from the equation (1) above. For example, a value D2 obtained by adding about 0.2 mm as a margin M to the equation (1) above as represented in an equation (2).

D2=\sqrt{R²−(R−z)²}+0.2 (2)

Accordingly, when the value obtained by adding the margin M is used, the state where the portion curved with a large curvature does not reach the root portion 44C may be further reliably implemented.

Actually, since the curve portion 44 has a certain degree of bending rigidity, the curve portion 44 is not bent sharply from the root portion 44C, and the curvature gradually increases as the distance from the root portion 44C increases.

Further, when the curve portion 44 is actually curved, a jig having a predetermined radius r may be used, and the curve portion 44 may be curved along the jig 70, as illustrated in FIG. 7. In this case, since the jig 70 partially supports the curve portion 44 from the internal side of the curve when the curve portion 44 is curved, the portion having a large curvature may be further effectively suppressed from reaching the root portion 44C. When the jig 70 is used, the radius r of the jig 70 may be adopted as the curvature radius R of the curve portion 44.

Even in a state where the jig 70 is removed from the curve portion 44, when the depth D is equal to or more than D1 obtained from the equation (1) above, the portion curved with a large curvature may be suppressed from reaching the root portion 44C. In addition, when the depth D is equal to or more than D2 obtained from the equation (2) above, the portion curved with a large curvature may be further reliably suppressed from reaching the root portion 44C.

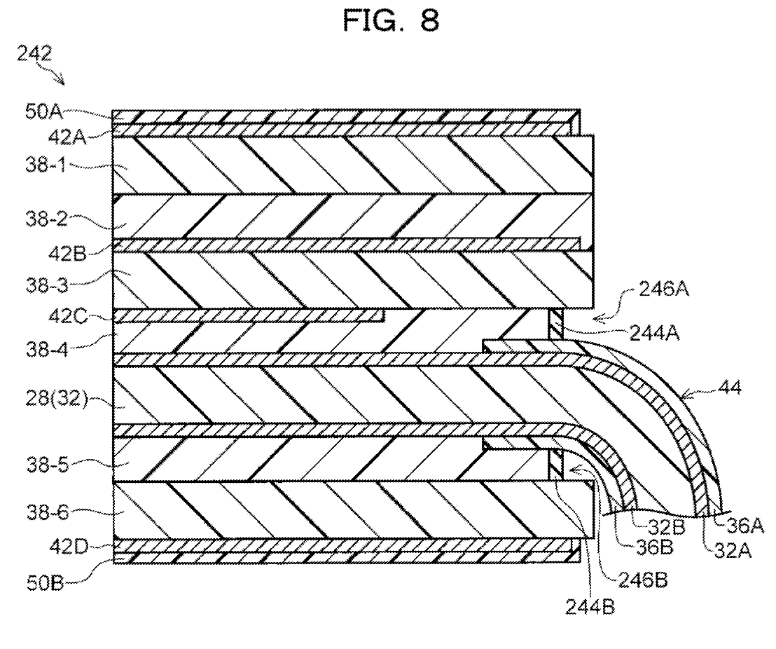

FIG. 8 represents a rigid flexible board 242 which is a modification of the second embodiment. In the rigid flexible board 242, the inner portions (the positions close to the fourth insulating layer 38-4) of the gaps 246A and 246B are filled with filling materials 244A and 244B. The filling materials 244A and 244B are formed of a material having elasticity, for example, a rubber.

As described above, the gaps 246A and 246B are filled with the filling materials 244A and 244B having elasticity so that the portion of the curve portion 44 which is curved with a large curvature is suppressed from reaching the root portion 44C. As compared to the structure in which the gaps are not filled with the filling materials 244A and 244B, the depths D of the gaps 246A and 246B may be reduced, that is, the width of the fourth insulating layer 38-4 may increase, and a large wiring area of the second pattern layer 42C may be secured.

Next, a third embodiment will be described. In the third embodiment, the same components, members and others as those of the first embodiment will be denoted by the same reference numerals as used in the first embodiment, and detailed descriptions thereof will be omitted. Further, since an electronic device of the third embodiment may adopt the same structure as that of the electronic device 24 of the first embodiment, illustration and detailed descriptions thereof will be omitted.

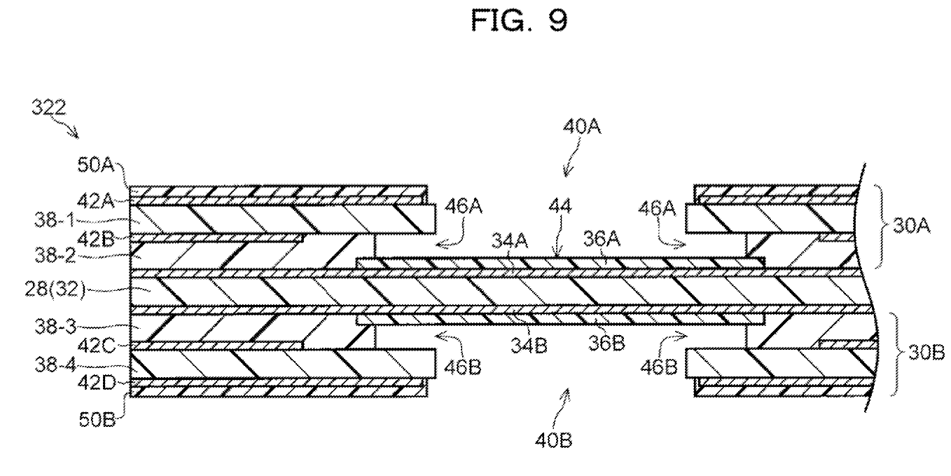

As illustrated in FIG. 9, in a rigid flexible board 322 of the third embodiment, the core layer 30A has two insulating layers (the first insulating layer 38-1 and the second insulating layer 38-2). The core layer 30B has two insulating layers (the third insulating layer 38-3 and the fourth insulating layer 38-4). The second pattern layer 42A is formed on the upper surface of the first insulating layer 38-1, the second pattern layer 42B is formed on the upper surface of the second insulating layer 38-2, the second pattern layer 42C is formed on the lower surface of the third insulating layer 38-3, and the second pattern layer 42D is formed on the lower surface of the fourth insulating layer 38-4.

The structure having the gap 46A may be implemented even in the structure in which the core layer 30A has two insulating layers as in the rigid flexible board 322 of the third embodiment. Identically, the structure having the gap 46A may be implemented even in the structure in which the core layer 30B has two insulating layers.

In the above-described embodiments, the example where the first pattern layers 34A and 34B are formed on the substrate 28 (the flexible layer 32) is described. Through the first patter layers, the structure of electrically connecting the laterally opposite core layers 30A or core layers 30B to each other may be implemented.

In addition, when the solder resist layers 36A and 36B as an example of protective layers cover the first pattern layers 34A and 34B, the first pattern layers 34A and 34B may be protected.

A structure in which the first pattern layers 34A and 34B are not formed on the substrate 28 (the flexible layer 32) may be adopted. Even in this structure, when glass fiber or the like is exposed on the surface of the substrate 28 thereby forming fine irregularities thereon, a stress concentration may easily occur on the irregularities. However, the solder resist layers 36A and 36B are provided on the substrate 28 (the flexible layer 32) so that the crack may be suppressed when the substrate 28 is curved at the curve portion 44.

The core layers 30A and 30B have the insulating layers 38 and the second pattern layers 42. That is, a structure in which the core layers 30A and 30B have a predetermined circuit pattern may be implemented.

When a plurality of core layers 30A and 30B and insulating layers 38 are provided, a structure having a predetermined thickness and rigidity may be implemented. Especially, as illustrated in FIG. 2, the core layers 30A and 30B are easy to be handled without being inadvertently deformed inside the case 26 of the electronic device 24.

The substrate 28 (the flexible layer 32) and the insulating layer 38 may be made of different materials, but when the same material (glass epoxy in the above-described embodiments) is used, the pressing may be performed under a constant condition, for example, a heat or a pressure during the pressing in the manufacturing, so that the manufacturing is facilitated. Further, when the same material is used for the flexible layer 32 and the insulating layer 38, the physical and chemical characteristics of the flexible layer 32 and the insulating layer 38 are consistent with each other so that high durability and reliability may be obtained, as compared to the structure of using different materials.

The substrate 28 (the flexible layer 32) is thinner than the core layers 30A and 30B and has low bending rigidity. That is, since the substrate 28 (the flexible layer 32) thinner than the core layers 30A and 30B is provided, the structure of the rigid flexible board having the curve portion 44 at the portion thereof may be easily implemented.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to an illustrating of the superiority and inferiority of the invention. Although the embodiments of the present invention have been described in detail, it should be understood that the various changes, substitutions, and alterations could be made hereto without departing from the spirit and scope of the invention.

What is claimed is:

1. A rigid flexible board comprising:
a substrate that has flexibility and electric insulation;
a protective layer formed at a central portion of each of opposite surfaces of the substrate; and
a plurality of core layers partially covering the protective layer and formed at a circumferential edge of each of the opposite surfaces of the substrate;
wherein a gap is formed close to a center of the substrate in a thickness direction thereof between the core layers and the protective layer.

2. The rigid flexible board according to claim 1, wherein the substrate has a first pattern layer formed of a conductive material, and the protective layer is a solder resist layer laminated on the first pattern layer.

3. The rigid flexible board according to claim 2, wherein each of the core layers includes an insulating layer having an insulating property, and a second pattern layer made of a conductive material and formed over the insulating layer.

4. The rigid flexible board according to claim 3, wherein the substrate and the insulating layer are formed of the same material.

5. The rigid flexible board according to claim 3, wherein a plurality of insulating layers are formed.

6. The rigid flexible board according to claim 1, wherein the substrate is thinner than the core layers.

7. The rigid flexible board according to claim 1, wherein a depth D (mm) of the gap from the center of the substrate toward the circumferential edge side is equal to or more than
D1=\sqrt{R²−(R−z)²} (1)
using a curvature radius R (mm) of a curved portion in a state where the substrate is curved, and a height z (mm) of the gap in the thickness direction.

8. An electronic device comprising:
a substrate that has flexibility and electric insulation;
a protective layer formed at a central portion of each of opposite surfaces of the substrate;
a plurality of core layers partially covering the protective layer and formed at a circumferential edge of each of the opposite surfaces of the substrate; and
an electronic part equipped on the core layers,
wherein a gap is formed close to a center of the substrate in a thickness direction thereof between the core layers and the protective layer.

9. The electronic device according to claim 8, wherein the substrate is curved.

10. A method for manufacturing a rigid flexible board which includes a substrate that has flexibility and electric insulation, and a protective layer formed at a central portion of each of opposite surfaces of the substrate, the method comprising:
forming a plurality of core layers over the substrate to partially cover the protective layer from a circumferential edge side of each of the opposite surfaces of the substrate, while forming a gap close to the central portion of the substrate in a thickness direction between the substrate and the protective layer.

11. The method according to claim 10, wherein
each of the core layers includes a plurality of insulating layers, and the plurality of insulating layers are collectively laminated on and pressed to the substrate.

12. The method according to claim 11, wherein
the pressing is performed after the protective layer formed over the substrate is cured.
